(19) United States
(12) Patent Application Publication
(10) Pub. No.: US 2026/0074932 A1
(43) Pub. Date: Mar. 12, 2026

(54) METHODS AND APPARATUS FOR REDUCING PULSE WIDTH DISTORTION AND/OR DELAY

(71) Applicant: Texas Instruments Incorporated, Dallas, TX (US)

(72) Inventors: Himanth Mudda, Kakinada (IN); Kumar Anurag Shrivastava, Bangalore (IN)

(21) Appl. No.: 19/309,022

(22) Filed: Aug. 25, 2025

(30) Foreign Application Priority Data
Sep. 11, 2024 (IN) 202441068874

(51) Int. Cl. H04L 27/04; G11C 11/24; H04L 27/06

(52) U.S. Cl. CPC H04L 27/04; H04L 27/06; G11C 11/24

(57) ABSTRACT

An example electronic circuit includes: a first circuit having an input and an output, the first circuit configured to provide a first voltage at the output of the first circuit based on an input signal at the input of the first circuit, the output of the first circuit coupled to a first node; a clamp circuit comprising a memory element configured to store a value based on the first voltage, the clamp circuit configured to inject a first current into the first node based on the value to increase the first voltage at the first node; and a comparator configured to generate an output signal corresponding to the input signal based on a comparison of the first voltage at the first node to a reference voltage.

### CROSS-REFERENCE TO RELATED APPLICATION

This application claims the benefit of and priority to Indian Provisional Patent Application No. 202441068874 filed Sep. 11, 2024, which is hereby incorporated herein by reference in its entirety.

### TECHNICAL FIELD

The present disclosure relates generally to an electronic system and method, and, in particular embodiments, to methods and apparatus to reduce pulse width distortion and/or delay.

### BACKGROUND

Some electrical systems utilize on-off keying (OOK) modulation protocols to transfer data from one device or circuit to another. For example, OOK may be used to transfer data between two circuits via an antenna or an isolation barrier (e.g., a circuit including one or more inductors). The OOK protocol includes outputting a modulated/analog signal via an antenna or isolated barrier to be obtained by a receiver circuit. The OOK modulated signal modulates to represent a first digital value (e.g., ‘1’) and does not modulate to represent a second digital value (e.g., ‘0’). The receiver circuit converts the modulated signal into a digital signal based on whether the OOK signal is modulating/oscillating or not modulating/oscillating.

### SUMMARY

In accordance to an embodiment, an electronic circuit includes: a first circuit having an input and an output, the first circuit configured to provide a first voltage at the output of the first circuit based on an input signal at the input of the first circuit, the output of the first circuit coupled to a first node; a clamp circuit including a memory element configured to store a value based on the first voltage, the clamp circuit configured to inject a first current into the first node based on the value to increase the first voltage at the first node; and a comparator configured to generate an output signal corresponding to the input signal based on a comparison of the first voltage at the first node to a reference voltage.

In accordance to an embodiment, an apparatus includes: a first supply voltage terminal; a second supply voltage terminal; a first transistor having first and second current path terminals, the first current path terminal of the first transistor coupled to the first supply voltage terminal, the second current path terminal of the first transistor coupled to the second supply voltage terminal; a first resistor coupled between the first supply voltage terminal and the first current path terminal of the first transistor; a comparator having a first input and a second input, the first input of the comparator coupled to the first current path terminal of the first transistor; a second transistor having a control terminal coupled to the second input of the comparator; a third transistor having a current path coupled to a current path of the second transistor; a fourth transistor having a control terminal coupled to a control terminal of the third transistor, and a current path coupled between the first supply voltage terminal and the first current path terminal of the first transistor; and a filter coupled between the control terminal of the third transistor and the control terminal of the fourth transistor.

In accordance to an embodiment, an electronic circuit includes: an input terminal; and a receiver circuit configured to receive a modulated signal via the input terminal, the receiver circuit including: a first circuit having an input coupled to the input terminal and an output, the first circuit configured to provide a first voltage at the output of the first circuit based on the modulated signal at the input of the first circuit, the output of the first circuit coupled to a first node; a clamp circuit including a memory element configured to store a value based on the first voltage, the clamp circuit configured to inject a first current into the first node based on the value to increase the first voltage at the first node; and a comparator configured to generate an output signal based on a comparison of the first voltage at the first node to a reference voltage.

In accordance to an embodiment, an electronic circuit includes: an input terminal configured to receive an on-off keying (OOK) modulated input signal, the OOK modulated input signal having a first state having a carrier signal, and a second state having a direct current (DC) voltage; an output terminal; an input stage having an input coupled to the input terminal, and an output coupled to the output terminal; and a comparator having an input coupled to the output terminal, where the input stage is configured to cause an output signal at the output terminal to: when the OOK modulated input signal has the first state, have a rise time that is based on a magnitude of the carrier signal; and when the OOK modulated input signal has the second state, have a fall time based on a value of a voltage at the output terminal when the carrier signal disappears.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates an example system for transmitting data between a first die and a second die, according to an embodiment of the present disclosure;

FIG. 2 illustrates an example system for receiving wireless data via an antenna, according to an embodiment of the present disclosure;

FIG. 3 is an example circuit diagram for implementing the receiver circuit of FIGS. 1 and/or 2, according to an embodiment of the present disclosure;

FIG. 4 is an alternative example circuit diagram for implementing the receiver circuit of FIGS. 1 and/or 2, according to an embodiment of the present disclosure;

FIG. 5 is an alternative example circuit diagram for implementing the bias circuit and the reference circuit of FIGS. 3 and/or 4, according to an embodiment of the present disclosure;

FIG. 6 is an alternative example circuit diagram for implementing the receiver circuit of FIGS. 1 and/or 2, according to an embodiment of the present disclosure;

FIG. 7 is an example timing diagram illustrating voltage and current signals for different portions of one or more of the receiver circuits of FIGS. 3-6, according to an embodiment of the present disclosure; and

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials, and the like. In some cases, known structures, materials, or operations are not shown or described in detail so as not to obscure the different aspects of the embodiments. References to “an embodiment” in this description indicate that a particular configuration, structure, or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Embodiments of the present disclosure are described in specific contexts, e.g., an automotive system, e.g., a remote keyless entry and visible light communication within an automobile. Some embodiments may be used in other circuits or applications, such as remote control systems, wireless sensors, optical communication systems, wireless alarm/doorbell systems, and/or any other system that can benefit from on-off keying modulation.

In some systems, a receiver circuit obtains an OOK signal and converts the modulated OOK signal into a digital signal using a circuit that operates as a low-pass filter. The settling of the circuit responsive to a change in the OOK signal depends on the carrier strength of the OOK signal. However, the carrier strength of the OOK signal may vary depending on process variation, isolation barrier gain, mismatches occurring during fabrication, etc. The variation may cause high pulse width distortion and high delay in the generation of the digital output. The pulse width distortion may be a function of the difference between the propagation delay time to logic high output (TPLH) to the propagation delay to logic low output (TPHL) (e.g., the larger the difference, the higher the pulse width distortion). The TPLH corresponds to a rise time that is based on a magnitude of the carrier signal and the TPHL corresponds to a fall time that is based on the value of the VOUT voltage when the carrier signal disappears.

In an embodiment, a voltage clamp is added to the receiver circuit to clamp the voltage at an input terminal of a comparator of the receiver circuit that generates the digital output corresponding to the modulated input signal. In such an embodiment, after the input signal transitions from a first state (e.g., modulating) to a second state (e.g., not modulating), the clamp allows the voltage at the input terminal of the comparator to settle faster than a system without the clamp. Because the settling time after the input signal transitions from modulating to not modulating corresponds to the TPHL delay, reducing the settling time of the voltage at the input terminal of the comparator reduces the TPHL delay closer to the TPLH delay, thereby reducing pulse width distortion without adding delay components (e.g., buffers).

In an embodiment, to further increase the settling time of the voltage at the input of the comparator of a receiver circuit, the voltage clamp can include a memory element. The memory element stores a charge corresponding to the input modulated signal. For example, if the input signal is modulating, the memory stores a charge, and if the input signal is not modulating, the memory discharges and then stores no charge. Accordingly, in response to the input modulated signal adjusting from modulating to not modulating, the memory can discharge the stored charge to help pull up the voltage at the first input terminal of the comparator, which decreases the settling time. Thus, because the settling time after the input signal transitions from modulating to not modulating corresponds to the TPHL delay, the memory element further reduces the TPHL delay closer to the TPLH delay, thereby reducing pulse width distortion without adding delay components (e.g., buffers).

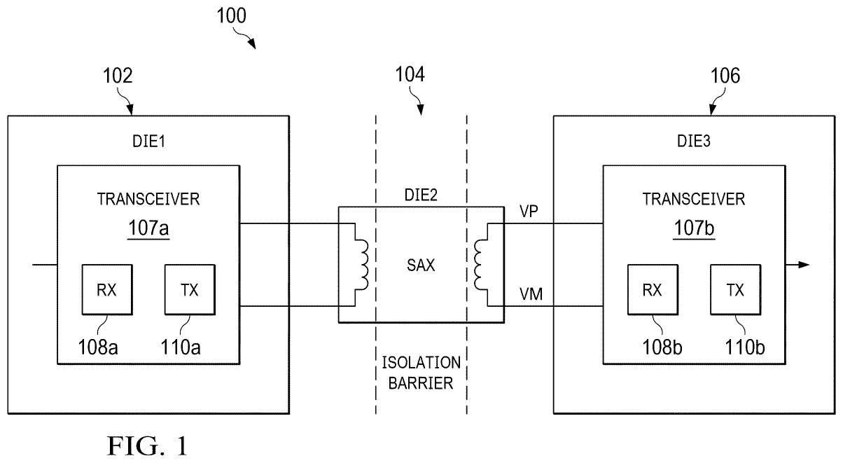

FIG. 1 is a block diagram of a system 100, according to an embodiment of the present disclosure. The system 100 includes a die 102, an isolation barrier die 104, and a die 106. The die 102 corresponds to a first circuit that includes the transceiver 107a, the isolation barrier die 104 corresponds to an isolation barrier, and the die 106 corresponds to a second circuit that includes the transceiver 107b. The transceiver 107a includes a receiver circuit (RX) 108a and a transmitter circuit 110a (TX). The transceiver 107b includes a receiver circuit (RX) 108b and a transmitter circuit (TX) 110b. Although the system 100 includes a transceiver in both dies 102, 106, the die 102 and/or the die 106 may include a dedicated receiver circuit and/or a dedicated transmitter circuit. Additionally, although the isolation barrier in the isolation barrier die 104 is implemented by a transformer circuit, the isolation barrier may be implemented by another isolation circuit (e.g., antennas, inductors, coils, winding, capacitors, etc.). Also, although the isolation barrier die 104 provides a differential output, the isolation barrier die 104 may provide a single-ended output and/or the differential output may be converted to a single-ended output. In some examples, the dies 102, 104, 106 are packaged into a single package. Other implementations are also possible.

In normal operation, the supply voltage(s) of the die 102 may be different than the supply voltage(s) of the die 106. In some examples, applying a signal directly from the die 102 to the die 106 can cause damage to one or more components of the die 106 due to the differences in the supply voltage(s). Thus, the isolation barrier die 104 includes an isolation barrier capable of facilitating bidirectional data transfer between the dies 102, 106. For example, the isolation barrier die 104 includes an isolation barrier capable of transmitting signals (e.g., an analog signal) from the die 102 to the die 106 without directly coupling the dies 102, 106.

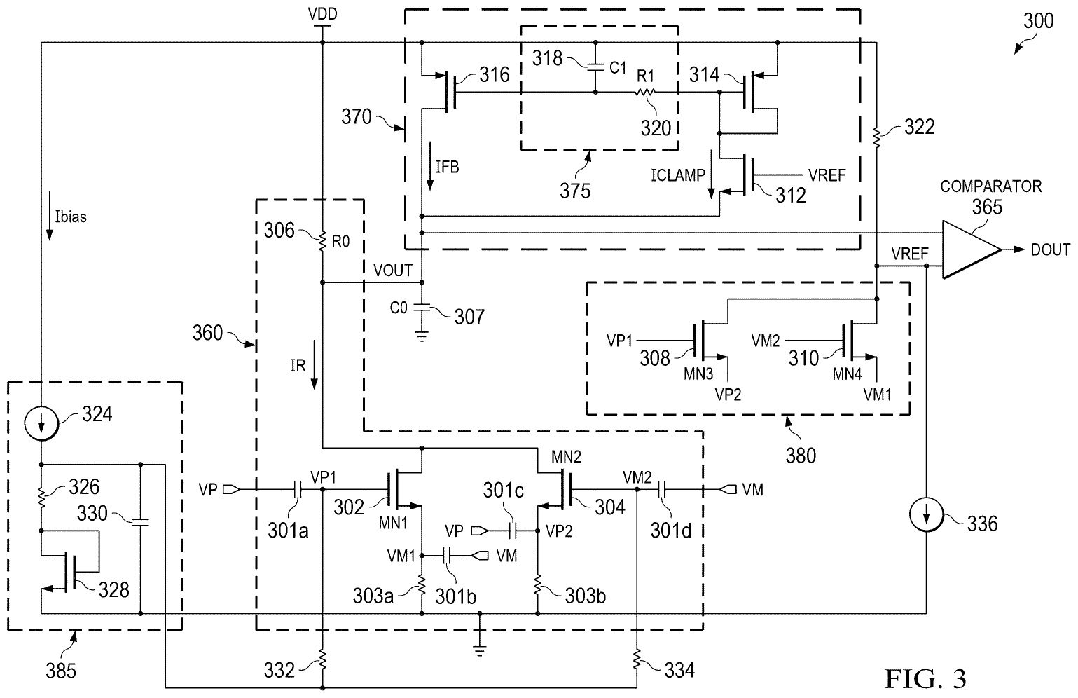

In some embodiments, a controller or other circuit of the die 102 generates a digital signal to send to the die 106. The controller or other circuit outputs the digital signal to the transmitter circuit 110a. The transmitter circuit 110a of the transceiver 107 converts the digital signal into an OOK signal. As described above, the OOK signal is an analog modulated signal that corresponds to a digital signal. For example, an OOK signal modulates for a first duration of time to represent a first digital value (e.g., ‘1’) and does not modulate for a second duration of time to represent a second digital value “0”). The transmitter 110a transmits an OOK signal to the receiver circuit 108b of the transceiver 107b via the isolation barrier of the isolation barrier die 104. When the modulated signal is output to the first side of the transformer, a corresponding signal is generated at the second side of the transformer. The signal at the second side of the transformer is received at the receiver circuit 108b as a differential signal (e.g., including a first signal VP and a second signal VM opposite the first signal). As further described below in conjunction with FIG. 3, the receiver circuit 108b includes a voltage clamp and/or a memory element that reduces pulse width distortion (PWD) and/or delay. Although the example of FIG. 1 corresponds to the die 102 transmitting an OOK signal (or other modulated signal) to the die 106 via the isolation barrier die 104, the die 106 may transmit an OOK or other modulated signal to the die 102 via the isolation barrier die 104.

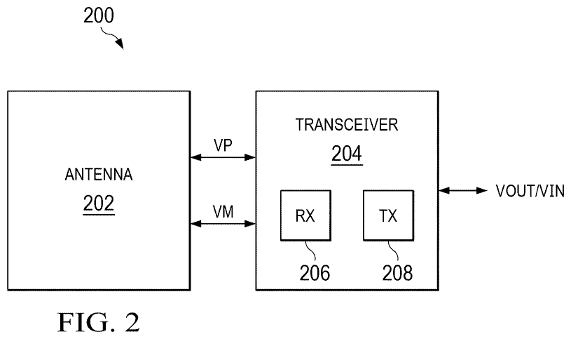

FIG. 2 is a block diagram of a system 200, according to an embodiment of the present disclosure. The system 200 includes an antenna 202, a transceiver 204, a receiver circuit 206, and a transmitter circuit 208. Although the system 200 includes the transceiver 204 coupled to a single antenna 202, the system 200 may include a dedicated receiver circuit and/or a dedicated transmitter circuit, each coupled to the same or different antennas. Also, although the antenna 202 provides a differential output, the antenna 202 may provide a single-ended output and/or the differential output may be converted to a single-ended output. Other implementations are also possible.

Instead of a connection to the isolation barrier die 104 of FIG. 1, the transceiver 204 of FIG. 2 may obtain an OOK signal and/or transmit an OOK signal via the antenna 202. The antenna wirelessly receives or transmits an OOK signal to/from another device or circuit. The input/output of the antenna 202 is a differential signal with the first portion of the signal output via the VP terminal and a second portion of the signal differential to the first portion output at the VM terminal. When the transmitter circuit 208 obtains a digital signal from another component (e.g., controller, processor, etc.) of the system 200, the transmitter circuit 208 outputs a differential OOK signal based on the digital signal via the differential terminals, VP and VM. When the receiver circuit 206 obtains a differential OOK signal from the antenna 202, the receiver circuit 206 converts the OOK signal into a digital signal to be output to one or more other components of the system 200.

FIG. 3 is an example circuit implementation of a receiver circuit 300, according to an embodiment of the present disclosure. The receiver circuit 300 may be used to implement the receiver circuit 108a, 108b, or 206 of FIGS. 1 and/or 2. Receiver circuit 300 includes rectifier circuit 360, a comparator 365, a clamp circuit 370, a memory element 375 (which may be implemented as or include a filter), a reference generation circuit 380 (which may be implemented as or include a voltage source), and a bias generation circuit 385.

The rectifier circuit 360 and the clamp circuit 370 may be referred to as an input stage. The rectifier circuit 360 includes input capacitors 301a-301d, transistors 302, 304, and resistors 303a, 303b, 306. The clamp circuit 370 includes transistors 312, 314, 216, and the memory element 375. The memory element 375 includes a capacitor 318 and a resistor 320. The reference generation circuit 380 includes transistors 308, 310. Receiver circuit 300 further includes resistor 322. The bias generation circuit 385 includes a current source 324, a resistor 326, a transistor 328, and a capacitor 330. In some examples, the clamp circuit 370 may not include the transistors 314, 316 and/or the memory element 375. Other implementations are also possible.

In normal operation, when the obtained OOK signal is not modulating (e.g., the OOK signal is a zero-voltage signal, the voltage at the VP and VM terminals is zero. Accordingly, when the OOK signal is not modulating, the transistors 302, 304 are off (e.g., operating in cutoff, non-conducting, and/or operating as an open switch) or operating in subthreshold region (e.g., where VOUT is close to VDD) near the cutoff region. Also, when the OOK signal is not modulating, the VOUT voltage at the VOUT terminal (also referred to as an output terminal) corresponds to the supply voltage VDD at the supply voltage VDD terminal and the resistance of the resistor 306. As further described below, the reference generation circuit 380 generates a VREF voltage at the VREF terminal. The comparator 365 compares the VOUT voltage to the VREF voltage to generate an output signal (e.g., a demodulated signal) based on the comparison. For example, when the VOUT voltage is above the VREF voltage, the comparator 365 outputs a first logic value (e.g., 0′). When the VOUT voltage is below the VREF voltage, the comparator 365 outputs a second logic value (e.g., 1′). However, in some examples, the inputs of the comparator 365 can be switched so that the outputs of the comparator 365 are flipped. Because the VOUT voltage is above the VREF voltage when the OOK signal is not modulating, the comparator 365 outputs the first logic value.

After a transition from the OOK signal not modulating to the OOK signal modulating, the VOUT voltage at the VOUT terminal decreases. For example, when the OOK signal modulates, the input voltage at the VP terminal modulates and the input voltage at the VM terminal modulates opposite of the input voltage at the VP terminal. Because (a) the input voltage at the VP terminal is coupled to the control terminal (e.g., the gate) of the transistor 302 and the second current path terminal (e.g., the source) of the transistor 304, (b) the voltage at the VM terminal is coupled to the control terminal of the transistor 304 and the second current path terminal (e.g., the source) of the transistor 302, and (c) a bias voltage near the threshold voltage of the transistors 302, 304 (Vth) is applied to the control terminals of the transistors 302, 304 (e.g., corresponding to the subthreshold region of the transistors 302, 304), then at least one of the transistors 302, 304 will be conducting (e.g., operating in linear mode or saturation mode). For example, VP+Vbias−VM>Vth or VM+Vbias−VP>Vth (e.g., where VP is the input voltage at the VP terminal, Vbias is the bias voltage at the control terminals of the transistor 302, 304, VM is the input voltage at the VM terminal, and Vth is the threshold voltage of the transistors 302, 304) all of the times while the OOK signal is modulating.

When the voltages at the control terminals of the transistors 302, 304 are modulating (e.g., analog sinusoidal voltage signals), IR current drawn from the supply voltage terminal VDD, through the resistor 306, through the current paths of the transistor 302, or the transistor 304 and through the ground voltage supply terminal (also referred to as a ground or a ground terminal) (e.g., via one of the resistors 303a, 303b) also modulates between 0 and a maximum current amount, thereby decreasing the VOUT voltage at the VOUT terminal. As used herein, a current path of a transistor is the connection between the first current path terminal and the second current path terminal when the transistor is conducting. When VOUT decreases a threshold voltage (e.g., of the comparator 365) below the VREF voltage, the comparator 365 changes its output to a second logic value. When the OOK signal transitions from no modulation to modulation, the amount of time it takes for the comparator 365 to change from the first logic value to the second logic value in response to the transition is the TPLH delay.

When the OOK signal transitions back to not modulating, the transistors 302, 304 no longer conduct and operate as open switches, thereby causing the VOUT voltage at the VOUT terminal to increase to a level above the VREF voltage. Due to the capacitor 307, which operates as a low-pass filter, there is some amount of settling time for the VOUT reference to increase to above the VREF voltage. The amount of time it takes for the VOUT voltage to settle and the comparator 365 to switch outputs to the first logic value is the TPHL delay. The settling time depends on carrier signal strength, which varies, as described above. Without the use of the clamp circuit 370, the variation causes TPHL to be much larger than TPLH, which corresponds to a large PWD. Some receiver circuits include buffers to increase the length of the TPLH to more closely match the TPHL, thereby reducing PWD. However, such circuits increase overall delay and lead to a slower receiver circuit.

In some embodiments, the receiver circuit 300 may advantageously decrease and/or eliminate PWD by reducing the TPHL delay (as opposed to increasing the TPLH delay) through the use of the clamp circuit 370. Thus, the receiver circuit 300 may advantageously result in better PWD with less delay than other receiver circuits. The clamp circuit 370 clamps the VOUT voltage at the VOUT terminal and prevents the VOUT voltage from dropping below a minimum value. In this manner, when the OOK signal transitions from modulating to not modulating, the amount of voltage that the VOUT voltage needs to increase by to settle above the VREF voltage is much less than a receiver circuit without the clamp circuit 370. Because the amount of voltage that the VOUT needs to increase by is lowered due to the clamp circuit 370, the TPHL delay decreases, which lowers the PWD.

In normal operation, as described above, when the OOK signal is not modulating, the VOUT voltage may be above the VREF voltage. Because the control terminal of the transistor 312 is coupled to the VREF terminal and the second current path terminal (e.g., the source) of the transistor 312 is coupled to the VOUT terminal, when the VOUT voltage is above the VREF voltage, the transistor 312 will not be conducting (e.g., operating as an open switch or in cutoff) or operating in the subthreshold region. Thus, the clamp circuit 370 is disabled after the OOK signal stops modulation or while the OOK signal is not modulating.

After the OOK signal transitions from not modulating to modulating, the VOUT voltage begins to decrease below the VREF voltage, as further described above. When the VREF voltage minus a threshold voltage of the transistor 312 is above the VOUT voltage, the transistor 312 conducts to draw the Iclamp current through the current path of the transistor 312, which pumps/injects current to the VOUT terminal to clamp the voltage at the VOUT terminal to a predefined voltage.

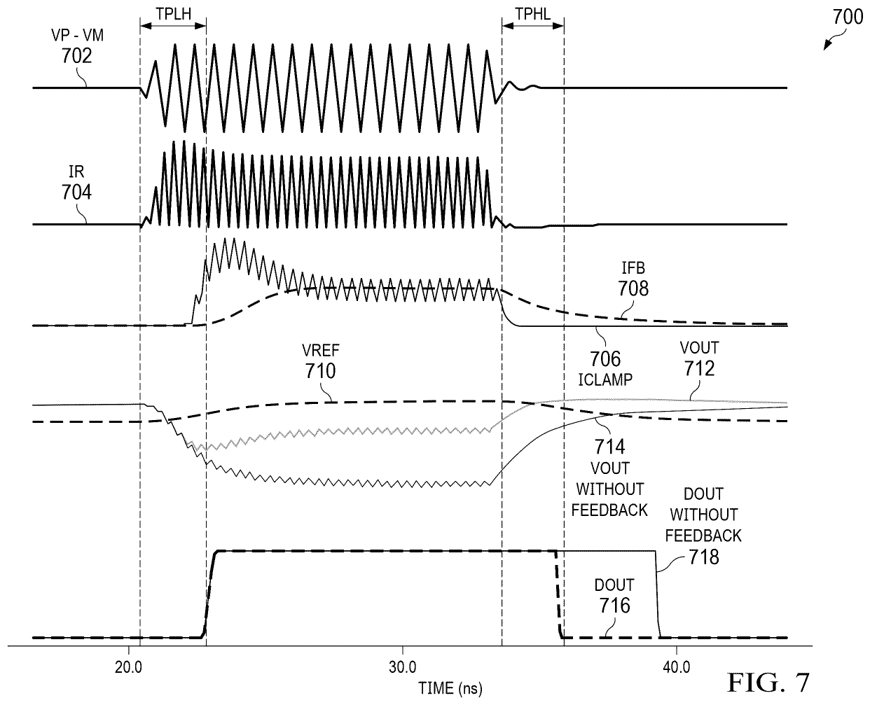

The clamp circuit 370 can further reduce the TPHL delay using a current mirror (e.g., corresponding to the transistors 314, 316) and the memory element 375. For example, the memory element 375 includes a capacitor 318 that stores a charge (e.g., corresponding to a non-zero value) when the OOK signal is modulating, resulting in the feedback current (Ifb) that flows into the VOUT node, to aid in the clamping of the VOUT voltage at the VOUT terminal. The Ifb current is a filtered current (e.g., based on the RC filter of the capacitor 318 and the resistor 320 of the memory element 375) of the Iclamp current, which is held by the capacitor 318 to charge the VOUT terminal when the OOK signal stops modulating. For example, after the OOK signal transitions from modulating to not modulating, although the Iclamp current quickly becomes zero, the stored charge in the capacitor 318 of the memory element 375 is released as the Ifb current to increase the VOUT voltage at the VOUT terminal faster than if the memory element 375 were not implemented. Example signal plots for the VOUT voltage, the VREF voltage, the Ir current through the current paths of one of the transistors 302, 304, the Iclamp current, the Ifb current, the output of the comparator (DOUT) is further described below in conjunction with FIG. 7.

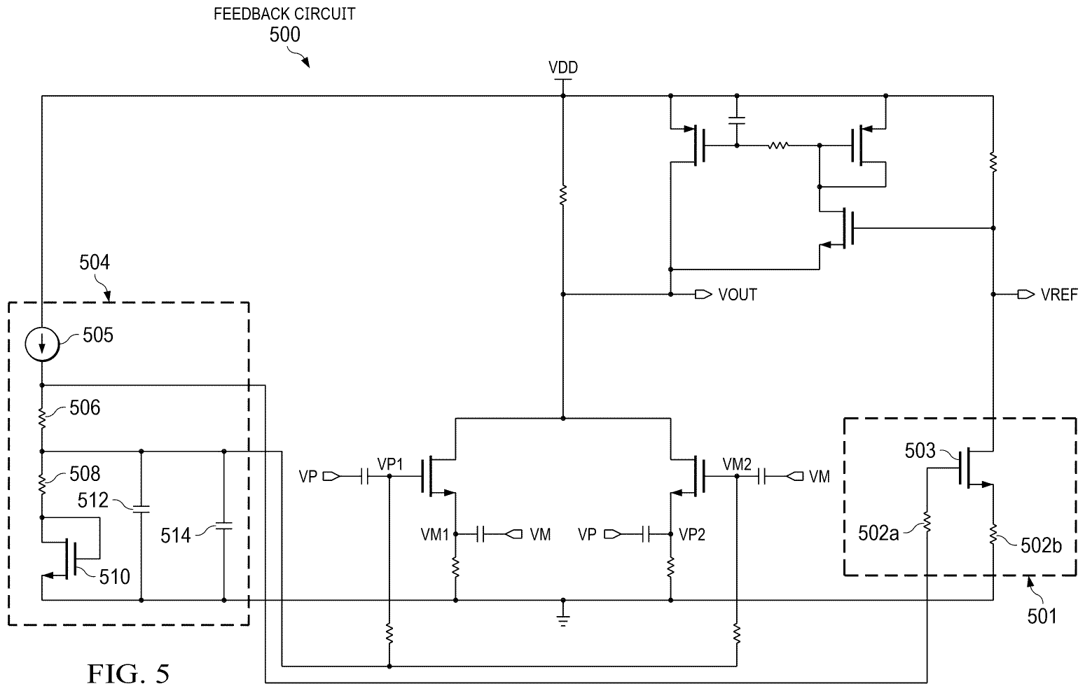

In some embodiments, the reference generation circuit 380, with the resistor 322, and the current source 366, generates the VREF voltage at the VREF terminal of the comparator 365. In the example of FIG. 3, the reference generation circuit 380 includes the transistors 308, 310 to cause the VREF voltage at the VREF terminal. However, the reference generation circuit 380 could be implemented in a different manner, such as with a voltage source or an impedance circuit, as further described below in conjunction with FIG. 5.

In some embodiments, as described above, the bias generation circuit 385 generates a bias voltage at the control terminals of the transistors 302, 304. The bias voltage is a voltage sufficient to ensure that when the OOK signal is modulating, at least one of the transistors 302, 304 is conducting. The bias generation circuit 385 includes the current source 324, the resistors 326, 332, 334, the transistor 328, and the capacitor 330 to generate the bias voltage at the control terminals of the transistors 302, 304. For example, the current source 324 causes current to flow across the resistors 326, 322, 334 to generate the bias voltage. The capacitor 330 is used to filter output AC signals. However, the bias circuit can be implemented by a different circuit, such as a voltage source or other circuit, as described below in conjunction with FIG. 5.

In the example of FIG. 3, the transistors 302, 304, 308, 310, 312, 328, are n-channel metal-oxide semiconductor field-effect transistors (MOSFETs), each with a control (gate) terminal, a first current path (drain) terminal, and a second current path (source) terminal. Alternatively, the transistors 302, 304, 308, 310, 312, 328 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 3, the transistors 314, 316 are p-channel MOSFETs, each with a control (gate) terminal, a first current path (source) terminal, and a second current path (drain) terminal. Alternatively, the transistors 314, 316 may be p-channel FETs, p-channel IGBTs, p-channel JFETs, PNP BJTs, or, with slight modifications, N-type equivalent devices.

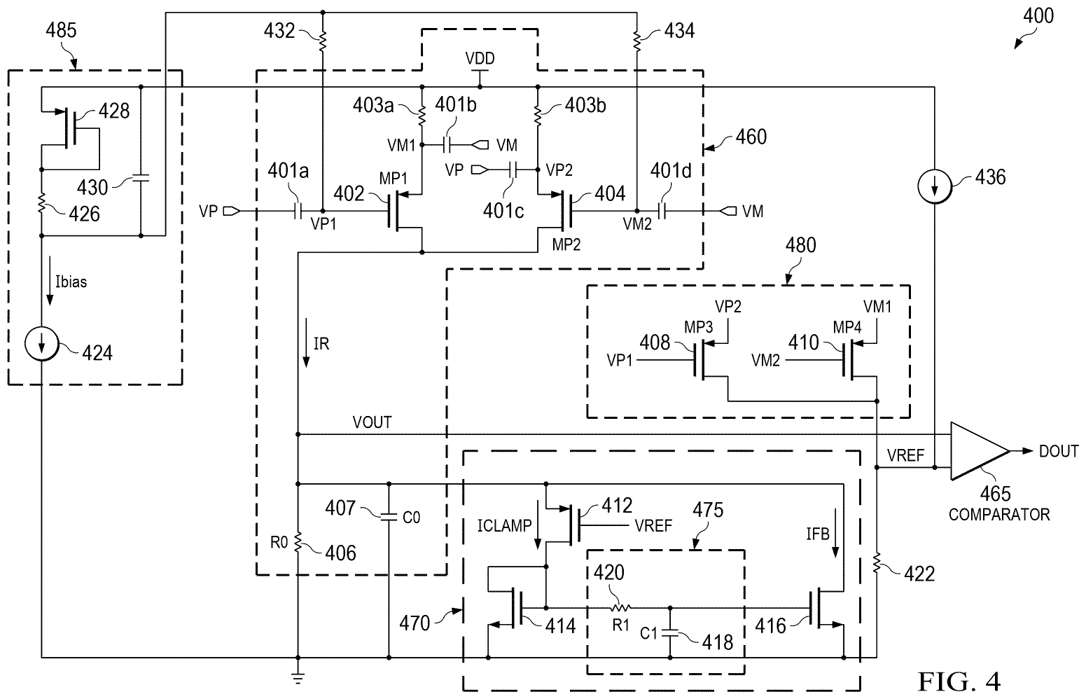

FIG. 4 is an example circuit implementation of a receiver circuit 400, according to an embodiment of the present disclosure. The receiver circuit 400 may be used to implement the receiver circuit 108a, 108b, or 206 of FIGS. 1 and/or 2. Receiver circuit 400 includes rectifier circuit 460, a comparator 465, a clamp circuit 470, a memory element 475, a reference generation circuit 480, and a bias generation circuit 485. In some examples, the rectifier circuit 460 and the clamp circuit 470 are referred to as an input stage. The rectifier circuit 460 includes input capacitors 401a-301d, transistors 402, 404, and resistors 403a, 403b, 406. The clamp circuit 470 includes transistors 412, 414, 216, and the memory element 475. The memory element 475 includes a capacitor 418 and a resistor 420. The reference generation circuit 480 includes transistors 408, 410. Receiver circuit 400 further includes resistor 422. The bias generation circuit 485 includes a current source 424, a resistor 426, a transistor 428, and a capacitor 430. In some examples, the clamp circuit 470 may not include the transistors 414, 416 and/or the memory element 475. Other implementations are also possible.

The receiver circuit 400 may operate in a substantially similar manner to the receiver 300. However, the receiver circuit 400 is structured to generate the VOUT volage that is below the VREF voltage when the input signal is not modulating and the VOUT voltage is above the VREF voltage when the input signal is modulating. For example, the supply terminals are flipped (VDD to ground and ground to VDD) and the transistors of the receiver circuit 300 are swapped (e.g., NMOS to PMOS and PMOS to NMOS).

Accordingly, in normal operation, as described above, when the OOK signal is not modulating, the VOUT voltage may be below the VREF voltage. Because the control terminal of the transistor 402 is coupled to the VREF terminal and the second current path terminal (e.g., the source) of the transistor 402 is coupled to the VOUT terminal, when the VOUT voltage is below the VREF voltage, the transistor 402 will not be conducting (e.g., operating as an open switch or in cutoff). Thus, the clamp circuit 401 is disabled after the OOK signal stops modulation or while the OOK signal is not modulating.

After the OOK signal transitions from not modulating to modulating, the VOUT voltage begins to increase above the VREF voltage. When the VREF voltage minus a threshold voltage of the transistor 402 is below the VOUT voltage, the transistor 402 conducts to draw the Iclamp current from the VOUT terminal to a ground supply terminal via the transistor 404, which clamps the voltage at the VOUT terminal to a predefined voltage.

The clamp circuit 401 can further reduce the TPHL delay using a current mirror (e.g., corresponding to the transistors 404, 406) and the memory element 407. For example, the memory element 407 includes a capacitor 408 that stores a charge when the OOK signal is modulating, resulting in the feedback current (Ifb) that flows out from the VOUT node toward the ground terminal, to aid in the clamping of the VOUT voltage at the VOUT terminal. The Ifb current is a filtered current (e.g., based on the RC filter of the capacitor 408 and the resistor 410 of the memory element 407) of the Iclamp current, which is held by the capacitor 408 to charge the VOUT terminal when the OOK signal stops modulating. For example, after the OOK signal transitions from modulating to not modulating, although the Iclamp current quickly becomes zero, the stored charge in the capacitor 408 of the memory element 475 is released as the Ifb current to decrease the VOUT voltage at the VOUT terminal faster than if the memory element 407 were not implemented.

In the example of FIG. 4, the transistors 402, 404, 408, 410, 412, 428 are p-channel metal-oxide semiconductor field-effect transistors (MOSFETs), each with a control (gate) terminal, a first current path (source) terminal, and a second current path (drain) terminal. Alternatively, the transistors 402, 404, 408, 410, 412, 428 may be p-channel field-effect transistors (FETs), p-channel insulated-gate bipolar transistors (IGBTs), p-channel junction field effect transistors (JFETs), PNP bipolar junction transistors (BJTs) or, with slight modifications, n-type equivalent devices. In the example of FIG. 4, the transistors 414, 416 are n-channel MOSFETs, with a control (gate) terminal, a first current path (drain) terminal, and a second current path (source) terminal. Alternatively, the transistors 414, 416 may be n-channel FETs, n-channel IGBTs, n-channel JFETs, NPN BJTs, or, with slight modifications, p-type equivalent devices.

FIG. 5 illustrates a receiver circuit 500 with an alternative implementation of the reference generation circuit 380 and the bias generation circuit 385, according to an embodiment of the present disclosure. The receiver circuit 500 may be used to implement the receiver circuit 108a, 108b, or 206 of FIGS. 1 and/or 2. The receiver circuit 500 includes the reference generation circuit 501, which includes resistors 502a, 502b and a transistor 503. The receiver circuit 500 further includes a bias generation circuit 504, which includes a current source 505, resistors 506, 508, a transistor 510, and capacitors 512, 514. Although the receiver circuit 500 includes the bias generation circuit 504 and the reference generation circuit 501 in conjunction with the clamp circuit 370 and the rectifier circuit 360, the bias generation circuit 504 and the reference generation circuit 501 could be implemented in conjunction with the receiver circuit 400.

The reference generation circuit 501 provides an alternative mechanism for generating the VREF voltage that is applied to the VREF terminal as an input to the comparator 365. The resistor 502a is structured to include a particular resistance corresponding to a particular voltage that is applied to the control terminal of the transistor 503, causing the transistor 503 to always be conducting. Because the transistor 503 is conducting, a current flows across the resistor 502, causing a particular VREF voltage at the VREF terminal. Thus, the resistance of the resistors 502a, 502 can be selected to ensure that the VREF voltage is set to a particular (e.g., user and/or manufacturer-defined) voltage.

The bias generation circuit 504 may operate substantially similar to the bias circuit 385. For example, the current source 505 operates in a similar manner to the current source 324, the resistor 508 operates in a similar manner to the resistor 326, the transistor 510 operates in a similar manner to the transistor 328, and the capacitor 512 operates in a similar manner to the capacitor 330. However, the bias generation circuit 504 further includes the resistor 506 and the capacitor 514. The resistor 506 aids in generating and/or varying the VREF voltage and adds process tracking for the VREF voltage. The capacitor 514 provides a low-pass filter for the current/voltage between the bias generation circuit 504 and the reference generation circuit 501.

In the example of FIG. 5, the transistors 503, 510, are n-channel metal-oxide semiconductor field-effect transistors (MOSFETs), each with a control (gate) terminal, a first current path (drain) terminal, and a second current path (source) terminal. Alternatively, the transistors 503, 510 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices.

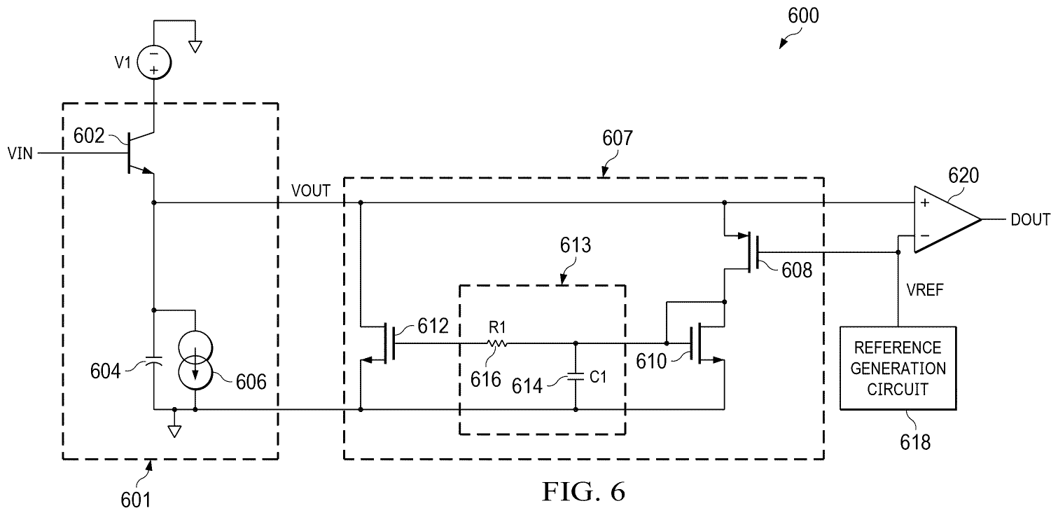

FIG. 6 is an example circuit implementation of a receiver circuit 600 for a single-ended input (Vin), according to an embodiment of the present disclosure. The single-ended input may be from a device that provides the single-ended input or a device that converts a differential input into a single-ended input. The receiver circuit 600 may be used to implement the receiver circuit 108a, 108b, or 206 of FIGS. 1 and/or 2. The receiver circuit 600 includes a converter circuit 601, which includes a transistor 602, a capacitor 604, and a current source 606, a clamp circuit 607, which includes a transistors 608, 610, 612, and a memory element 613, which includes a capacitor 614 and a resistor 616, a reference generation circuit 618, and a comparator 620. In some examples, the clamp circuit 607 may not include the transistors 610, 612 and/or the memory element 613. Other implementations are also possible.

In some embodiments, the converter circuit 601 converts the input OOK signal (VIN) to a VOUT signal (e.g., a peak detection enable (PKDET) signal) at the VOUT terminal. In normal operation, when the input OOK signal is not modulating, the voltage at the control (base) terminal of the transistor 602 is DC or nearly DC (e.g., approximately 1.5 V). Thus, when the input OOK signal is not modulating, the transistor 602 operates in cutoff or linear mode (e.g., where the VOUT voltage is approximately 1 V). Because the VREF voltage generated by the reference generation circuit 618 is above the VOUT voltage when the OOK signal is not modulating, the comparator 620 outputs a logic low voltage. In some examples, the transistor 602 is biased in the subthreshold region.

When the input OOK signal is modulating, the voltage at the control terminal of the transistor 602 modulates (e.g., a sinusoidal voltage between 0.5 V and 2.5 V), the transistor 602 conducts to cause a portion of the supply voltage to be applied to the VOUT terminal and be stored in the capacitor 604, resulting in an increase of the VOUT voltage (e.g., from 1 V when the OOK signal is not modulating to 2 V when the OOK signal is modulating). The increased VOUT voltage (e.g., when OOK signal is modulating) is higher than the VREF voltage generated by the reference generation circuit 618. Accordingly, the comparator 620 outputs a logic high voltage after the OOK signal starts modulating.

As described above, the TPLH delay is the amount of time it takes for the comparator 620 to adjust its output in response to the OOK signal adjusting from not modulating to modulating and the TPHL delay is the amount of time it takes for the comparator 620 to adjust its output in response to the OOK signal adjusting from modulating to non-modulating. Charging the VOUT node using the transistor 602 and the capacitor 604 is fast, but discharging the VOUT varies, which can lead to large PWD. Accordingly, the receiver circuit 600 includes the clamp circuit 607 to reduce the TPHL by clamping how high the VOUT can be when the OOK signal is modulating. In this manner, the amount of voltage reduction for the VOUT voltage is less with the clamp circuit 607 than without the clamp circuit 607, thereby corresponding to a faster TPHL that is more similar to the TPLH. Thus, the clamp circuit 607 reduces PWD without adding delay.

The operation of the clamp circuit 607 may be substantially similar to the clamp circuit 470. For example, the transistors 608, 610, 612 operate in the same manner as the transistor 412, 414, 416, the capacitor 614 operates in the same manner as the capacitor 418, and the resistor 616 operates in the same manner as the resistor 420. Additionally, the reference generation circuit 618 may be implemented by the reference generation circuit 380, the reference generation circuit 501, and/or by any other circuit capable of generating a reference voltage.

In the example of FIG. 6, the transistors 610, 612, are n-channel metal-oxide semiconductor field-effect transistors (MOSFETs), each with a control (gate) terminal, a first current path (drain) terminal, and a second current path (source) terminal. Alternatively, the transistors 610, 612 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 6, the transistor 608 is a p-channel MOSFET, with a control (gate) terminal, a first current path (source) terminal, and a second current path (drain) terminal. Alternatively, the transistor 608 may be a p-channel FET, a p-channel IGBT, a p-channel JFET, a PNP BJT, or, with slight modifications, an N-type equivalent device. In the example of FIG. 6, the transistor 602 is an NPN bipolar junction transistor (BJT), with a control (base) terminal, a first current path (collector) terminal, and a second current path (emitter) terminal. Alternatively, the transistor 602 may be an n-channel MOSFET, an n-channel field-effect transistor (FET), an n-channel insulated-gate bipolar transistor (IGBT), an n-channel junction field effect transistor (JFET), or, with slight modifications, a p-type equivalent device.

FIG. 7 is a timing diagram 700 that includes various voltage plots and current plots corresponding to the receiver circuit 300, according to an embodiment of the present disclosure. However, the timing diagram 700 may be described in conjunction with any of the receiver circuits of FIGS. 3-5. The timing diagram 700 includes an input voltage differential plot 702, an IR plot 704, an Iclamp plot 706, an Ifb plot 708, a VREF plot 710, a VOUT plot 712, a VOUT without feedback plot 714, a DOUT plot 716, and a DOUT plot without the feedback 718. The input voltage differential plot 702 corresponds to the difference between the voltage at the VP terminal and the voltage at the VM terminal of FIG. 3. The IR plot 704 corresponds to the IR current that flows into one of the transistors 302, 304 of FIG. 3. The Iclamp plot 706 corresponds to the current through the current path of the transistor 312. The Ifb plot 708 corresponds to the current through the current path of the transistor 316. The VREF plot 710 corresponds to the VREF voltage at the VREF terminals of FIG. 3. The VOUT plot 712 corresponds to the voltage at the VOUT terminal of FIG. 3. The VOUT without feedback plot 714 corresponds to the VOUT terminal of FIG. 3 if the clamp circuit 370 is not included. The DOUT plot 716 corresponds to the output of the comparator 365. The DOUT plot without the feedback 718 corresponds to the output of the comparator 365 if the clamp circuit 370 is not included.

The VP-VM plot 702 is initially not modulating, modulates for a duration of time, and then stops modulating. Initially, when the VP-VM pot 702 is not modulating, the IR plot 704, the Iclamp plot 706, and the Ifb plot 708 are zero. Thus, the VOUT plots 712, 714 are higher than the VREF plot 710, thereby corresponding to a logic low for the DOUT plots 716, 718. After the VP-VM plot 702 begins to oscillate, the IR plot 704 likewise begins to oscillate, causing the VOUT plots 712, 714 to decrease. When the VOUT plots 712, 714 decrease below a threshold amount (e.g., a threshold voltage of the comparator 365) below the VREF plot 710, the DOUT plots 716, 718 increase from a logic low output to a logic high output. Additionally, when the VOUT plots 712, 714 decrease a threshold amount (e.g., a threshold voltage of the transistor CC) below the VREF plot 710, the Iclamp plot 706 increases from zero, thereby injecting the Iclamp current to the VOUT node. Also, the Ifb plot 708 increases due to the charging of the capacitor 318. The Iclamp current (and the Ifb current) clamps the VOUT plot 712 to a minimum voltage while the VOUT without feedback plot 714 decreases below the minimum voltage.

When the VP-VM plot 702 stops oscillating, the IR plot 704 also stops oscillating, causing the VOUT plots 712, 712 to increase. Because the VOUT plot 712 was clamped to a minimum voltage, the amount of time it takes for the VOUT plot 712 to increase above the VREF plot 710 is smaller than the amount of time it takes for the VOUT without feedback plot 714 to increase above the VREF plot 710. Also, after the VP-VM plot 702 and IR plot 704 stop modulating, the capacitor 318 discharges to slowly decrease the Ifb current (as shown in the Ifb plot 708) into the VOUT terminal, thereby increasing the VOUT plot 712 at a faster rate than the VOUT without feedback plot 714. Thus, the DOUT plot 716 returns to the logic low output faster than the DOUT plot without feedback 718. Accordingly, the TPHL delay of the DOUT plot 716 is shorter and more similar to the TPLH delay than the TPHL delay of the DOUT without feedback plot 718.

While an example manner of implementing the receiver circuits 108a, 108b, 206 of FIGS. 1 and/or 2 is illustrated in FIGS. 3-6, one or more of the elements, processes, and/or devices illustrated in FIG. 3-6 may be combined, divided, re-arranged, omitted, eliminated, and/or implemented in any other way. Further, one or more portions of the receiver circuit 300, 400, 500, 600 of FIGS. 3-6, may be implemented by hardware alone or by hardware in combination with software and/or firmware. Thus, for example, any one or more portions of the receiver circuit 300, 400, 500, 600 of FIGS. 3-6, could be implemented by programmable circuit, processor circuit, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the one or more portions of the receiver circuit 300, 400, 500, 600 of FIGS. 3-6 may include one or more elements, processes, and/or devices in addition to, or instead of, those illustrated in FIGS. 3-6, and/or may include more than one of any or all of the illustrated elements, processes and devices.

Example embodiments of the present disclosure are summarized here. Other embodiments can also be understood from the entirety of the specification and the claims filed herein.

Example 1. An electronic circuit including: a first circuit having an input and an output, the first circuit configured to provide a first voltage at the output of the first circuit based on an input signal at the input of the first circuit, the output of the first circuit coupled to a first node; a clamp circuit including a memory element configured to store a value based on the first voltage, the clamp circuit configured to inject a first current into the first node based on the value to increase the first voltage at the first node; and a comparator configured to generate an output signal corresponding to the input signal based on a comparison of the first voltage at the first node to a reference voltage.

Example 2. The electronic circuit of example 1, where the first circuit includes a rectifier configured to convert the input signal into rectified current, where the first voltage is based on the rectified current.

Example 3. The electronic circuit of one of examples 1 or 2, where the input signal is an analog signal corresponding to on-off keying modulation.

Example 4. The electronic circuit of one of examples 1 to 3, where the value is a non-zero value when the input signal is oscillating and the value is a zero value when the input signal is not oscillating, and where the first current is zero when the value is the zero value.

Example 5. The electronic circuit of one of examples 1 to 4, where the memory element includes a low-pass filter to store the value, the low-pass filter including a resistor and a capacitor.

Example 6. The electronic circuit of one of examples 1 to 5, where the clamp circuit is configured to inject the first current into the first node to clamp the first voltage to prevent the first voltage from reducing below a threshold voltage.

Example 7. The electronic circuit of one of examples 1 to 6, further including an antenna coupled to the input of the first circuit, the antenna configured to provide the input signal.

Example 8. The electronic circuit of one of examples 1 to 7, further including: an isolation barrier coupled to the input of the first circuit; and a second circuit configured to provide the input signal to the input of the first circuit via the isolation barrier.

Example 9. The electronic circuit of one of examples 1 to 8, where the isolation barrier includes a transformer having a first winding coupled to the second circuit, and a second winding coupled to the input of the first circuit.

Example 10. The electronic circuit of one of examples 1 to 9, where the first circuit is implemented in a first semiconductor die, the second circuit is implemented in a second semiconductor die, and the isolation barrier is implemented in a third semiconductor die, where the first, second, and third semiconductor dies are packaged in a single package.

Example 11. The electronic circuit of one of examples 1 to 10, where the first circuit, the clamp circuit, and the comparator are part of a receiver or a transceiver.

Example 12. The electronic circuit of one of examples 1 to 11, where the comparator includes a first input terminal and a second input terminal, the first input terminal coupled to the first node, the second input terminal coupled to a second node, where: the first circuit includes: a first transistor having a first current path terminal, a second current path terminal, and a control terminal, the first current path terminal of the first transistor coupled to the first node and a first supply voltage terminal, the second current path terminal of the first transistor coupled to a second supply voltage terminal, the control terminal of the first transistor coupled to a first input (VP) terminal; and a second transistor having a first current path terminal, a second current path terminal, and a control terminal, the first current path terminal of the second transistor coupled to the first node, the first supply voltage terminal, and the first current path terminal of the second transistor, the second current path terminal of the second transistor coupled to the second supply voltage terminal, the control terminal of the second transistor coupled to a second input (VM) terminal; the clamp circuit includes: a third transistor having a first current path terminal, a second current path terminal, and a control terminal, the first current path terminal of the third transistor coupled to the first supply voltage terminal, the second current path terminal coupled to the first node; a fourth transistor having a first current path terminal, a second current path terminal, and a control terminal, the first current path terminal of the fourth transistor coupled to the first supply voltage terminal, the second current path terminal of the fourth transistor coupled to the control terminal of the fourth transistor; and a fifth transistor having a first current path terminal, a second current path terminal, and a control terminal, the first current path terminal of the fifth transistor coupled to the second current path terminal and the control terminal of the fourth transistor, the second current path terminal of the fifth transistor coupled to the first node, the control terminal of the fifth transistor coupled to the second node; and the memory element includes: a resistor coupled between the control terminal of the third transistor and the control terminal of the fourth transistor; and a capacitor coupled between the first supply voltage terminal and the control terminal of the third transistor.

Example 13. An apparatus including: a first supply voltage terminal; a second supply voltage terminal; a first transistor having first and second current path terminals, the first current path terminal of the first transistor coupled to the first supply voltage terminal, the second current path terminal of the first transistor coupled to the second supply voltage terminal; a first resistor coupled between the first supply voltage terminal and the first current path terminal of the first transistor; a comparator having a first input and a second input, the first input of the comparator coupled to the first current path terminal of the first transistor; a second transistor having a control terminal coupled to the second input of the comparator; a third transistor having a current path coupled to a current path of the second transistor; a fourth transistor having a control terminal coupled to a control terminal of the third transistor, and a current path coupled between the first supply voltage terminal and the first current path terminal of the first transistor; and a filter coupled between the control terminal of the third transistor and the control terminal of the fourth transistor.

Example 14. The apparatus of example 13, further including a voltage source coupled to the second input of the comparator.

Example 15. The apparatus of one of examples 13 or 14, where the first transistor includes a control terminal coupled to a second input (VP) terminal, further including a fifth transistor having a first current path terminal, a second current path terminal, and a control terminal, the first current path terminal of the fifth transistor coupled to the first current path terminal of the first transistor, the first input of the comparator and the first supply voltage terminal, the second current path terminal of the fifth transistor coupled to the second supply voltage terminal, the control terminal of the fifth transistor coupled to a first input (VM) terminal.

Example 16. The apparatus of one of examples 13 to 15, where the voltage source includes: a sixth transistor having a first current path terminal, a second current path terminal, and a control terminal, the first current path terminal of the sixth transistor coupled to the second input of the comparator, the second current path terminal of the sixth transistor coupled to the second current path terminal of the fifth transistor, the control terminal of the sixth transistor coupled to the control terminal of the first transistor; and a seventh transistor having a first current path terminal, a second current path terminal, and a control terminal, the first current path terminal of the seventh transistor coupled to the second input of the comparator and the second current path terminal of the fifth transistor, the second current path terminal of the seventh transistor coupled to the second current path terminal of the first transistor, the control terminal of the seventh transistor coupled to the control terminal of the fifth transistor.

Example 17. The apparatus of one of examples 13 to 16, where the voltage source includes: a sixth transistor having a first current path terminal, a second current path terminal, and a control terminal, the first current path terminal of the sixth transistor coupled to the second input of the comparator; a second resistor having a first terminal coupled to the control terminal of the sixth transistor and a second terminal coupled to the first voltage supply terminal; and a third resistor having a first terminal coupled to the second current path terminal of the sixth transistor and a second terminal coupled to the second voltage supply terminal.

Example 18. The apparatus of one of examples 13 to 17, further including: a current source having a first terminal coupled to the first voltage supply terminal and a second terminal; a second resistor having a first terminal coupled to the second terminal of the current source and a second terminal; a fifth transistor having a first current path terminal, a second current path terminal, and a control terminal, the first current path terminal coupled to the second terminal of the second resistor and the control terminal of the fifth transistor, the second current path terminal coupled to the second voltage supply terminal; and a capacitor having a first terminal and a second terminal, the first terminal of the capacitor coupled to the second terminal of the current source and the first terminal of the second resistor, the second terminal of the capacitor coupled to the second voltage supply terminal.

Example 19. The apparatus of one of examples 13 to 18, further including: a first input (VM) terminal, the first input (VM) terminal configured to provide a first signal, where the second current path terminal of the first transistor is coupled to the first input (VM) terminal; a second input (VP) terminal, the second input (VP) terminal configured to provide a second signal differential to the first signal, where the first transistor includes a control terminal coupled to a second input (VP) terminal; and a fifth transistor having a first current path terminal, a second current path terminal, and a control terminal, the first current path terminal of the fifth transistor coupled to the first current path terminal of the first transistor, the first resistor, a current path terminal of the fourth transistor, and a current path terminal of the second transistor, the second current path terminal of the fifth transistor coupled to the control terminal of the first transistor, the second input (VP) terminal, and the second supply voltage terminal, the control terminal of the fifth transistor coupled to the first input (VM) terminal and the second current path terminal of the first transistor.

Example 20. The apparatus of one of examples 13 to 19, further including: a first capacitor coupled between the second input (VP) terminal and the control terminal of the first transistor; a second capacitor coupled between the first input (VM) terminal and the control terminal of the fifth transistor; a third capacitor coupled between the first input (VM) terminal and the second current path terminal of the first transistor; a fourth capacitor coupled between the second input (VP) terminal and the second current path terminal of the fifth transistor; a second resistor coupled between the second current path terminal of the first transistor and the second voltage supply terminal; and a third resistor coupled between the second current path terminal of the fifth transistor and the second voltage supply terminal.

Example 21. The apparatus of one of examples 13 to 20, where the first transistor has a control terminal coupled to an input terminal, further including: a capacitor having a first terminal and a second terminal, the first terminal of the capacitor coupled to the first current path terminal of the first transistor, the first input of the comparator, and the first input of the first transistor, the second terminal of the capacitor coupled to a ground terminal; and a current source having a first terminal and a second terminal, the first terminal of the current source coupled to the first terminal of the capacitor, the first current path terminal of the first transistor, the first input of the comparator, and the first input of the first transistor, the second current path terminal of the current source coupled to the ground terminal.

Example 22. The apparatus of one of examples 13 to 21, further including: a capacitor having a first terminal coupled to the first supply voltage terminal and a second terminal coupled to the control terminal of the fourth transistor; and a second resistor having a first terminal and a second terminal, the first terminal of the second resistor coupled to the second terminal of the capacitor and the control terminal of the fourth transistor, the second terminal of the second resistor coupled to the control terminal of the third transistor.

Example 23. An electronic circuit including: an input terminal; and a receiver circuit configured to receive a modulated signal via the input terminal, the receiver circuit including: a first circuit having an input coupled to the input terminal and an output, the first circuit configured to provide a first voltage at the output of the first circuit based on the modulated signal at the input of the first circuit, the output of the first circuit coupled to a first node; a clamp circuit including a memory element configured to store a value based on the first voltage, the clamp circuit configured to inject a first current into the first node based on the value to increase the first voltage at the first node; and a comparator configured to generate an output signal based on a comparison of the first voltage at the first node to a reference voltage.

Example 24. The electronic circuit of example 23, where the modulated signal is an OOK signal, and where an output of the comparator is configured to provide a demodulated signal based on the modulated signal.

Example 25. The electronic circuit of one of examples 23 or 24, further including: a transmitter circuit configured to transmit the modulated signal; and an isolation barrier configured to wirelessly transmit the modulated signal to the receiver circuit, the isolation barrier to electronically isolate the transmitter circuit from the receiver circuit.

Example 26. The electronic circuit of one of examples 23 to 25, where the transmitter circuit is a first transmitter circuit and the receiver circuit is a first receiver circuit, further including: a second receiver circuit coupled to the first transmitter circuit and the isolation barrier, the first transmitter circuit and the second receiver circuit making up a first transceiver; and a second transmitter circuit coupled to the first receiver circuit and the isolation barrier, the second transmitter circuit and the first receiver circuit making up a second transceiver, the isolation barrier corresponding to bidirectional data transfer between the first transceiver and the second transceiver.

Example 27. The electronic circuit of one of examples 23 to 26, where the transmitter circuit is implemented in a first die, the isolation barrier is implemented in a second die, and the receiver circuit is implemented in a third die.

Example 28. The electronic circuit of one of examples 23 to 27, further including an antenna coupled to the input terminal, the antenna configured to provide the modulated signal.

Example 29. An electronic circuit including: an input terminal configured to receive an on-off keying (OOK) modulated input signal, the OOK modulated input signal having a first state having a carrier signal, and a second state having a direct current (DC) voltage; an output terminal; an input stage having an input coupled to the input terminal, and an output coupled to the output terminal; and a comparator having an input coupled to the output terminal, where the input stage is configured to cause an output signal at the output terminal to: when the OOK modulated input signal has the first state, have a rise time that is based on a magnitude of the carrier signal; and when the OOK modulated input signal has the second state, have a fall time based on a value of a voltage at the output terminal when the carrier signal disappears.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An electronic circuit comprising:
a first circuit having an input and an output, the first circuit configured to provide a first voltage at the output of the first circuit based on an input signal at the input of the first circuit, the output of the first circuit coupled to a first node;
a clamp circuit comprising a memory element configured to store a value based on the first voltage, the clamp circuit configured to inject a first current into the first node based on the value to increase the first voltage at the first node; and
a comparator configured to generate an output signal corresponding to the input signal based on a comparison of the first voltage at the first node to a reference voltage.

2. The electronic circuit of claim 1, wherein the first circuit comprises a rectifier configured to convert the input signal into rectified current, wherein the first voltage is based on the rectified current.

3. The electronic circuit of claim 1, wherein the input signal is an analog signal corresponding to on-off keying modulation.

4. The electronic circuit of claim 1, wherein the value is a non-zero value when the input signal is oscillating and the value is a zero value when the input signal is not oscillating, and wherein the first current is zero when the value is the zero value.

5. The electronic circuit of claim 1, wherein the memory element includes a low-pass filter to store the value, the low-pass filter comprising a resistor and a capacitor.

6. The electronic circuit of claim 1, wherein the clamp circuit is configured to inject the first current into the first node to clamp the first voltage to prevent the first voltage from reducing below a threshold voltage.

7. The electronic circuit of claim 1, further including an antenna coupled to the input of the first circuit, the antenna configured to provide the input signal.

8. The electronic circuit of claim 1, further comprising:
an isolation barrier coupled to the input of the first circuit; and
a second circuit configured to provide the input signal to the input of the first circuit via the isolation barrier.

9. The electronic circuit of claim 8, wherein the isolation barrier comprises a transformer having a first winding coupled to the second circuit, and a second winding coupled to the input of the first circuit.

10. The electronic circuit of claim 9, wherein the first circuit is implemented in a first semiconductor die, the second circuit is implemented in a second semiconductor die, and the isolation barrier is implemented in a third semiconductor die, wherein the first, second, and third semiconductor dies are packaged in a single package.

11. The electronic circuit of claim 1, wherein the first circuit, the clamp circuit, and the comparator are part of a receiver or a transceiver.

12. The electronic circuit of claim 1, wherein the comparator includes a first input terminal and a second input terminal, the first input terminal coupled to the first node, the second input terminal coupled to a second node, wherein:
the first circuit includes:
a first transistor having a first current path terminal, a second current path terminal, and a control terminal, the first current path terminal of the first transistor coupled to the first node and a first supply voltage terminal, the second current path terminal of the first transistor coupled to a second supply voltage terminal, the control terminal of the first transistor coupled to a first input (VP) terminal; and
a second transistor having a first current path terminal, a second current path terminal, and a control terminal, the first current path terminal of the second transistor coupled to the first node, the first supply voltage terminal, and the first current path terminal of the second transistor, the second current path terminal of the second transistor coupled to the second supply voltage terminal, the control terminal of the second transistor coupled to a second input (VM) terminal;
the clamp circuit includes:
a third transistor having a first current path terminal, a second current path terminal, and a control terminal, the first current path terminal of the third transistor coupled to the first supply voltage terminal, the second current path terminal coupled to the first node;
a fourth transistor having a first current path terminal, a second current path terminal, and a control terminal, the first current path terminal of the fourth transistor coupled to the first supply voltage terminal, the second current path terminal of the fourth transistor coupled to the control terminal of the fourth transistor; and
a fifth transistor having a first current path terminal, a second current path terminal, and a control terminal, the first current path terminal of the fifth transistor coupled to the second current path terminal and the control terminal of the fourth transistor, the second current path terminal of the fifth transistor coupled to the first node, the control terminal of the fifth transistor coupled to the second node; and
the memory element includes:
a resistor coupled between the control terminal of the third transistor and the control terminal of the fourth transistor; and
a capacitor coupled between the first supply voltage terminal and the control terminal of the third transistor.

13. An apparatus comprising:
a first supply voltage terminal;
a second supply voltage terminal;
a first transistor having first and second current path terminals, the first current path terminal of the first transistor coupled to the first supply voltage terminal, the second current path terminal of the first transistor coupled to the second supply voltage terminal;
a first resistor coupled between the first supply voltage terminal and the first current path terminal of the first transistor;
a comparator having a first input and a second input, the first input of the comparator coupled to the first current path terminal of the first transistor;
a second transistor having a control terminal coupled to the second input of the comparator;
a third transistor having a current path coupled to a current path of the second transistor;
a fourth transistor having a control terminal coupled to a control terminal of the third transistor, and a current path coupled between the first supply voltage terminal and the first current path terminal of the first transistor; and
a filter coupled between the control terminal of the third transistor and the control terminal of the fourth transistor.

14. The apparatus of claim 13, further comprising a voltage source coupled to the second input of the comparator.

15. The apparatus of claim 14, wherein the first transistor includes a control terminal coupled to a second input (VP) terminal, further including a fifth transistor having a first current path terminal, a second current path terminal, and a control terminal, the first current path terminal of the fifth transistor coupled to the first current path terminal of the first transistor, the first input of the comparator and the first supply voltage terminal, the second current path terminal of the fifth transistor coupled to the second supply voltage terminal, the control terminal of the fifth transistor coupled to a first input (VM) terminal.

16. The apparatus of claim 15, wherein the voltage source includes:
a sixth transistor having a first current path terminal, a second current path terminal, and a control terminal, the first current path terminal of the sixth transistor coupled to the second input of the comparator, the second current path terminal of the sixth transistor coupled to the second current path terminal of the fifth transistor, the control terminal of the sixth transistor coupled to the control terminal of the first transistor; and
a seventh transistor having a first current path terminal, a second current path terminal, and a control terminal, the first current path terminal of the seventh transistor coupled to the second input of the comparator and the second current path terminal of the fifth transistor, the second current path terminal of the seventh transistor coupled to the second current path terminal of the first transistor, the control terminal of the seventh transistor coupled to the control terminal of the fifth transistor.

17. The apparatus of claim 15, wherein the voltage source includes:
a sixth transistor having a first current path terminal, a second current path terminal, and a control terminal, the first current path terminal of the sixth transistor coupled to the second input of the comparator;
a second resistor having a first terminal coupled to the control terminal of the sixth transistor and a second terminal coupled to the first voltage supply terminal; and
a third resistor having a first terminal coupled to the second current path terminal of the sixth transistor and a second terminal coupled to the second voltage supply terminal.

18. The apparatus of claim 13, further including:
a current source having a first terminal coupled to the first voltage supply terminal and a second terminal;
a second resistor having a first terminal coupled to the second terminal of the current source and a second terminal;
a fifth transistor having a first current path terminal, a second current path terminal, and a control terminal, the first current path terminal coupled to the second terminal of the second resistor and the control terminal of the fifth transistor, the second current path terminal coupled to the second voltage supply terminal; and
a capacitor having a first terminal and a second terminal, the first terminal of the capacitor coupled to the second terminal of the current source and the first terminal of the second resistor, the second terminal of the capacitor coupled to the second voltage supply terminal.

19. The apparatus of claim 13, further including:
a first input (VM) terminal, the first input (VM) terminal configured to provide a first signal, wherein the second current path terminal of the first transistor is coupled to the first input (VM) terminal;
a second input (VP) terminal, the second input (VP) terminal configured to provide a second signal differential to the first signal, wherein the first transistor includes a control terminal coupled to a second input (VP) terminal; and
a fifth transistor having a first current path terminal, a second current path terminal, and a control terminal, the first current path terminal of the fifth transistor coupled to the first current path terminal of the first transistor, the first resistor, a current path terminal of the fourth transistor, and a current path terminal of the second transistor, the second current path terminal of the fifth transistor coupled to the control terminal of the first transistor, the second input (VP) terminal, and the second supply voltage terminal, the control terminal of the fifth transistor coupled to the first input (VM) terminal and the second current path terminal of the first transistor.

20. The apparatus of claim 19, further including:
a first capacitor coupled between the second input (VP) terminal and the control terminal of the first transistor;
a second capacitor coupled between the first input (VM) terminal and the control terminal of the fifth transistor;
a third capacitor coupled between the first input (VM) terminal and the second current path terminal of the first transistor;
a fourth capacitor coupled between the second input (VP) terminal and the second current path terminal of the fifth transistor;
a second resistor coupled between the second current path terminal of the first transistor and the second voltage supply terminal; and
a third resistor coupled between the second current path terminal of the fifth transistor and the second voltage supply terminal.

21. The apparatus of claim 13, wherein the first transistor has a control terminal coupled to an input terminal, further including:
a capacitor having a first terminal and a second terminal, the first terminal of the capacitor coupled to the first current path terminal of the first transistor, the first input of the comparator, and the first input of the first transistor, the second terminal of the capacitor coupled to a ground terminal; and
a current source having a first terminal and a second terminal, the first terminal of the current source coupled to the first terminal of the capacitor, the first current path terminal of the first transistor, the first input of the comparator, and the first input of the first transistor, the second current path terminal of the current source coupled to the ground terminal.

22. The apparatus of claim 13, further including:
a capacitor having a first terminal coupled to the first supply voltage terminal and a second terminal coupled to the control terminal of the fourth transistor; and
a second resistor having a first terminal and a second terminal, the first terminal of the second resistor coupled to the second terminal of the capacitor and the control terminal of the fourth transistor, the second terminal of the second resistor coupled to the control terminal of the third transistor.
